(19) United States
(12) Patent Application Publication
(10) Pub. No.: US 2013/0078812 A1
(43) Pub. Date: Mar. 28, 2013

(54) Wafer Carrier with Flexible Pressure Plate

(71) Applicants: Larry A. Spiegel, San Luis Obispo, CA (US); William J. Kalenian, San Luis Obispo, CA (US)

(72) Inventors: Larry A. Spiegel, San Luis Obispo, CA (US); William J. Kalenian, San Luis Obispo, CA (US)

(73) Assignee: Strasbaugh

(21) Appl. No.: 13/243,808

(22) Filed: Sep. 23, 2011

(51) Int. Cl. H01L 21/306; B24B 41/06

(52) U.S. Cl. 438/692; 451/388; 257/E21.23

(57) ABSTRACT

A wafer carrier with a wafer mounting plate disposed under a plenum which can be pressurized and depressurized to alter the shape of the wafer mounting plate and a plenum, formed with the wafer mounting plate and the wafer itself, to which vacuum can be applied to hold the wafer to the wafer mounting plate during polishing

### FIELD OF THE INVENTIONS

The inventions described below relate the field of wafer carriers and particularly to wafer carriers used during chemical mechanical planarization of silicon wafers.

### BACKGROUND OF THE INVENTIONS

Integrated circuits, including computer chips, are manufactured by building up layers of circuits on the front side of silicon wafers. An extremely high degree of wafer flatness and layer flatness is required during the manufacturing process. Chemical-mechanical planarization (CMP) is a process used during device manufacturing to flatten wafers and the layers built-up on wafers to the necessary degree of flatness.

Chemical-mechanical planarization is a process involving polishing of a wafer with a polishing pad combined with the chemical and physical action of a slurry pumped onto the pad. The wafer is held by a wafer carrier, with the backside of the wafer facing the wafer carrier and the front side of the wafer facing a polishing pad. The polishing pad is held on a platen, which is usually disposed beneath the wafer carrier. Both the wafer carrier and the platen are rotated so that the polishing pad polishes the front side of the wafer. A slurry of selected chemicals and abrasives is pumped onto the pad to affect the desired type and amount of polishing. (CMP is therefore achieved by a combination of chemical softener and physical downward force that removes material from the wafer or wafer layer.)

Using the CMP process, a thin layer of material is removed from the front side of the wafer or wafer layer. The layer may be a layer of oxide grown or deposited on the wafer or a layer of metal deposited on the wafer. The removal of the thin layer of material is accomplished so as to reduce surface variations on the wafer. Thus, the wafer and layers built-up on the wafer are very flat and/or uniform after the process is complete. Typically, more layers are added and the chemical mechanical planarization process repeated to build complete integrated circuit chips on the wafer surface. Wafers are provided with flat edges or notches that are used to orient the wafers for various steps in the process. Wafers are provided in uniform sizes, including 150 mm wafers which have been available for some time and are typically flat edged (called flatted wafers), and newer 200 mm and 300 mm wafers which are round and notched (called round wafers or notched wafers).

In the current CMP process addressed by the devices and methods described below, uniformity of the wafer polishing has not been perfect. The wafers, when polished with current CMP systems, often exhibit faster polishing (faster removal rates) either at the center of the wafer or the edge of the wafer. This is referred to as center-fast polishing or center-slow polishing. With more demanding integrated circuit designs, previously tolerable center-fast polishing or center-slow polishing, and the resultant slight non-uniformity in the wafer surface, are no longer tolerable. For example, GMR heads (giant magneto-resistive heads) for hard disk drives are formed on wafers, and these wafers are subject to significant bow and warp, although total thickness variation is minimal. The bow and warp results in non-uniform polishing across the surface of the wafer. The bowing and warping is not consistent from wafer to wafer, and a solution for compensating for this bow and warp is needed.

### SUMMARY

The methods and devices described below provide for a wafer carrier adapted to further reduce the center-slow and center-fast polishing and allow a wafer to be more uniformly polished across its entire surface. In a new system for chemical mechanical planarization, a wafer carrier with a wafer mounting plate is provided with numerous protrusions on its bottom surface, such that a vacuum can be applied to the resultant space between the wafer mounting plate and a wafer. The wafer mounting plate is significantly stiffer than the wafer, so the suction forces the wafer to comply to the shape of the mounting plate. The carrier includes a shape control plenum above the mounting plate. The shape control plenum may be pressurized or subject to vacuum to alter the shape of the wafer mounting plate to compensate for center-slow and center-fast polishing process.

### BRIEF DESCRIPTION OF THE DRAWINGS

FIG. 1 shows a system for performing chemical mechanical planarization.

FIG. 2 shows a cross section of the lower portion of a wafer carrier with a ceramic wafer mounting plate with pins on the lower surface for establishing a vacuum plenum between the wafer mounting plate and a wafer.

FIG. 3 is a cross section of the pinned wafer mounting plate.

FIG. 4 is an elevational view of the pinned wafer mounting plate.

FIG. 5 is a cross section of the pinned wafer mounting plate preformed with a convex bottom surface.

### DETAILED DESCRIPTION OF THE INVENTIONS

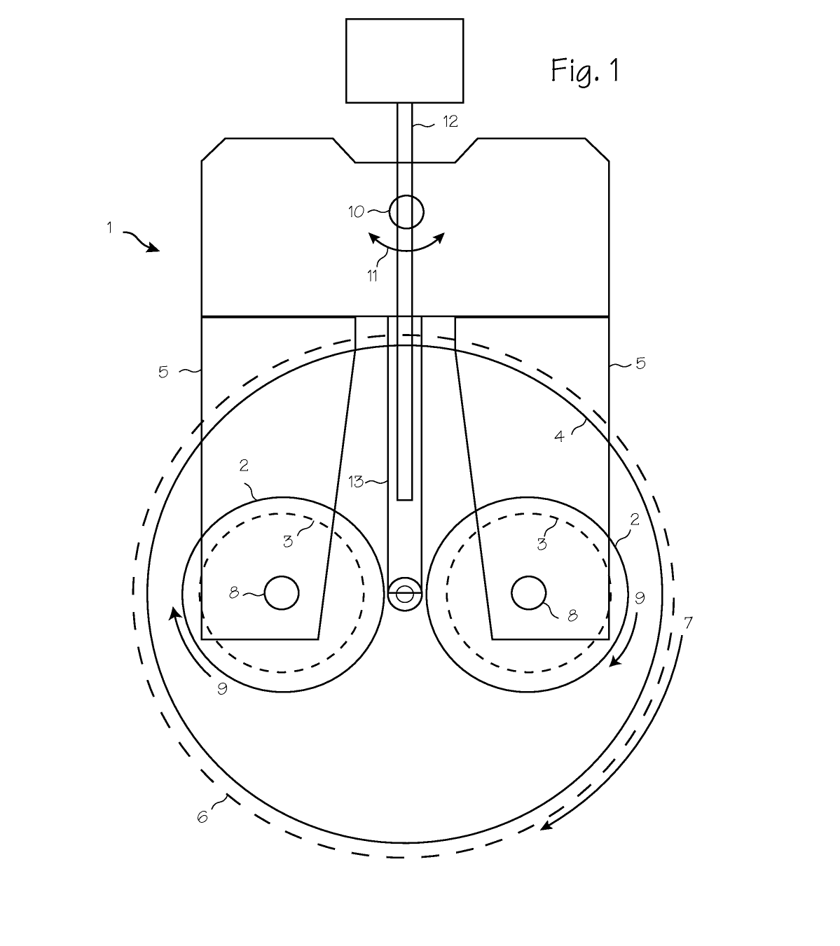

FIG. 1 shows a system 1 for performing chemical mechanical planarization. One or more polishing heads or wafer carriers 2 hold wafers 3 (shown in phantom to indicate their position underneath the wafer carrier) suspended over a polishing pad 4. The wafer carriers are suspended from translation arms 5. The polishing pad is disposed on a platen 6, which spins in the direction of arrows 7. The wafer carriers 2 rotate about their respective spindles 8 in the direction of arrows 9. The wafer carriers are also translated back and forth over the surface of the polishing pad by the translating spindle 10, which moves as indicated by arrows 11. The slurry used in the polishing process is injected onto the surface of the polishing pad through slurry injection tube 12, which is disposed on or through a suspension arm 13. (Other chemical mechanical planarization systems may use only one wafer carrier that holds one wafer, or may use several wafer carriers that hold several wafers. Other systems may also use separate translation arms to hold each carrier.)

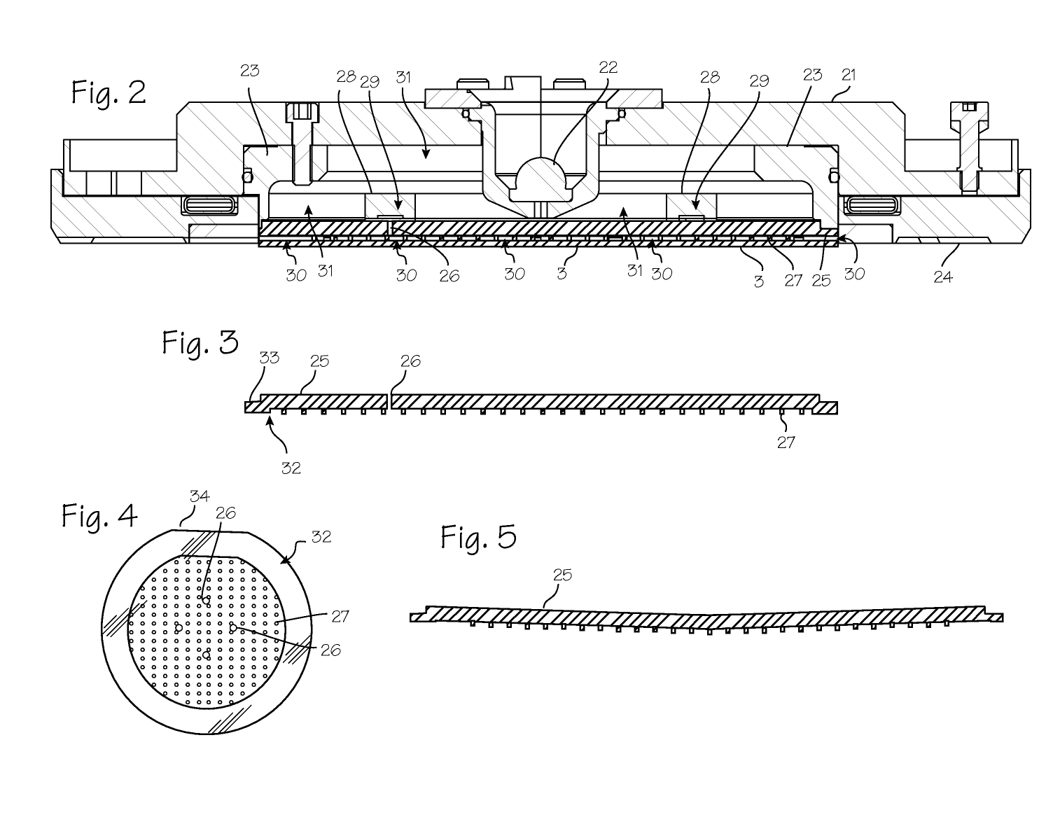

FIG. 2 shows a cross section of the wafer carrier subassembly with a ceramic wafer mounting plate with pins on the lower surface for establishing a vacuum plenum between the wafer mounting plate and a wafer. The wafer carrier includes a manifold plate 21 (also referred to as a mounting plate) for attaching the wafer carrier to a carrier housing and top plate (not shown) through the pivot mechanism 22, and the spindles 8. FIG. 2 also shows a plenum ring 23 disposed within the carrier housing, a retaining ring 24, and a wafer mounting plate 25. The wafer mounting plate includes a vacuum channel 26 formed through the wafer mounting plate to establish fluid communication between the upper side of the plate and the lower side of the plate. The wafer mounting plate includes a number of downwardly depending protrusions 27. A vacuum manifold in the form of vacuum ring 28 is disposed above the wafer mounting plate, and includes an annular groove or channel 29 in the bottom surface of the ring which serves as a vacuum plenum in fluid communication with the vacuum channel 26. Vacuum may be applied to the vacuum ring through a vacuum means which may include suitable fittings on the top of the vacuum ring, tubing connecting to a vacuum pump, and channels within the vacuum ring in fluid communication with the channel 29. The vacuum ring provides a convenient vacuum manifold, but any form of manifold may be used to provide a pathway for fluid communication between the vacuum channels and the vacuum source, and distribute vacuum to various vacuum channels in the wafer mounting plate.

When a wafer is disposed beneath the wafer mounting plate, vacuum may be applied to the vacuum ring to draw the wafer into contact with the wafer mounting plate. The space 30 established by the protrusions, between the wafer mounting plate and the wafer, constitutes a vacuum plenum which distributes suction over the upper surface of the wafer. This secures the wafer to the wafer mounting plate. The volume 31 within the plenum ring 23 constitutes a shape control plenum, and can be pressurized or depressurized (subjected to suction) to apply force to the wafer mounting plate in order to deform it. The shape control plenum is supplied with pressurized fluid or suction through a fluid supply means which may include any appropriate tubing and ports in the manifold plate (which includes necessary channels and fittings to provide fluid and/or apply vacuum to the shape control plenum and the vacuum plenum) and pressurized reservoirs, pressure pumps or vacuum pumps. The shape control plenum is pneumatically sealed. The joint between the wafer mounting plate 25 and the plenum ring 23 is sealed with adhesive, and other joints may be sealed with ring seals and o-rings. The joint between the vacuum ring 28 and the wafer mounting plate is also sealed with adhesive. The wafer mounting plate may also be formed integrally with other components, such as the plenum ring, to simplify construction.

FIG. 3 is a cross section of the pinned wafer mounting plate 25 with the downwardly depending protrusions 27. The main disk of the mounting plate may be about 3.175 to 7.65 mm (⅛ to 0.300 inch) thick. The diameter of the mounting plate matches the diameter of the wafer which it holds. The protrusions depicted in this illustration are cylindrical pins, with flat ends, and a diameter of about 0.53975 mm ( 1/32″) and height of about 0.53975 mm ( 1/32″), spaced about 1.5875 mm ( 1/16″) apart. These dimensions provide for an adequate plenum space, with spacing tight enough to ensure that the wafer is cannot be deformed between the pins. Preferably, there are no protrusions near the perimeter 32 of the wafer mounting plate. The perimeter may be raised, with the flat annular ridge shown in FIG. 3, to seal the vacuum space between the wafer and the wafer mounting plate. This ridge is preferably the same height, relative to the flat bottom of the wafer mounting plate, as the protrusions. The spacing of the protrusions may be varied, so long as the spacing is not so wide that individual pins might deform the wafer bottom surface which would lead to over-polishing opposite the pins. Although the wafer mounting plate protrusions are depicted as cylinders in the illustration, the protrusions may be formed in various shapes. Preferably, the protrusions are sized and dimensioned, and space apart, so as to provide sufficient plenum space so that the applied vacuum is effective to hold the wafer to the wafer mounting plate without allowing any significant deformation of the wafer between the protrusions. The edge of the upper surface of the wafer mounting plate is rabbeted, to provide a shoulder 33 which can be glued to the lower surface of the plenum ring 23. The wafer mounting plate is preferably very stiff, so that any wafer mounting on the plate will conform to the shape of the mounting plate. However, the mounting plate is preferably deformable by the applied pressure or vacuum in the shape control plenum. Alumina (aluminum oxide) and other ceramics are suitable materials for the mounting plate. Other materials may be used, provided that they are dimensionally stable and non-reactive with the wafers or slurry used in the polishing process.

The wafer mounting plate is generally round, but may be flatted, as shown in FIG. 4, and flat, as shown in the cross section of FIG. 3. For use with flatted wafers, the flatted wafer mounting plate may have a corresponding flat 34, of similar arc as the wafer, though flatted wafers may be processed with a carrier with a round, un-flatted retaining ring. The retaining ring may be provided with a circular segment to fill the otherwise empty space between the retaining ring and the flatted edge of the mounting plate and wafer. In the elevational view of FIG. 4, the protrusions 27, vacuum port 26, bare perimeter 32, and flat 34 are visible. The wafer mounting plate may be preformed in a concave or convex shape. As shown in FIG. 5, the wafer mounting plate is convex (relative to the wafer, the bottom surface is convex). This convex wafer mounting plate is useful for wafers of known concave deformity or expected center-fast processing. The convexity can be enhanced or diminished by the application of positive or negative pressure in the shape control plenum. The wafer mounting plate may also be concave (relative to the wafer) for use with wafers of known convex deformity or expected center-slow processing. The curvature shown in FIG. 5 is greatly exaggerated for illustrative purposes, and the actual curvature of the wafer mounting plate need only be a few microns.

In use, as the wafer is polished and rotated by the carrier head as described above in relation to FIG. 1, vacuum is applied to the space below the wafer mounting plate, through the vacuum ring 28 and annular groove 29 and vacuum ports 26. The vacuum, and the friction between the protrusions and back surface of the wafer, are sufficient to hold the wafer in place relative to the wafer mounting plate and the retaining ring, thus limiting relative movement between the carrier and the wafer. While vacuum is applied between the wafer and wafer mounting plate, positive pressure or negative pressure (vacuum) is applied to the shape control plenum 31 to warp the wafer mounting plate into a concave or convex shape, as desired to compensate for expected center-fast or center-slow polishing. Flexure of the wafer mounting plate is on the order of a few microns, which is sufficient to compensate for center-slow and center-fast processes. For ceramic wafer mounting plates with the thickness stated above, deflection at the center of the wafer mounting plate should be about 5 microns per PSI of pressure or vacuum. At the same time, the wafer mounting plate is stiff, relative to the very thin wafer, such the that wafer will conform to the shape of the bottom of the wafer mounting plate when suction is applied to the wafer. Wafer mounting plates may be 150, 200, or 300 mm in diameter. When comprised of ceramic such as alumina, thickness in the range of 3.175 to 7.65 mm (⅛ to 0.300 inch) thick will provide the necessary rigidity vis-à-vis the wafer while allowing for deflection due to the pressure in the shape control plenum.

While the preferred embodiments of the devices and methods have been described in reference to the environment in which they were developed, they are merely illustrative of the principles of the inventions. The elements of the various embodiments may be incorporated into each of the other species to obtain the benefits of those elements in combination with such other species, and the various beneficial features may be employed in embodiments alone or in combination with each other. For example, the pins or protrusions on the wafer mounting plate may be used to obtain the benefit of this feature, either alone or in combination with the flexure of the wafer mounting plate. Also, the sealed wafer shaping plenum and the flexible wafer mounting plate may be used without pins to obtain the benefit of those features either alone or in combination with the vacuum plenum and protrusions to obtain the benefit of the flexure of the wafer mounting plate. Other embodiments and configurations may be devised without departing from the spirit of the inventions and the scope of the appended claims.

We claim:

1. A wafer carrier for polishing a wafer, said wafer carrier comprising:
a manifold plate, plenum ring and wafer mounting plate defining a shape control plenum;
a retaining ring coaxially disposed about the wafer mounting plate and defining, in conjunction with a lower surface of the wafer mounting plate, a space configured to accommodate a wafer;
fluid supply means for providing pressurized fluid or suction to the shape control plenum;
a vacuum channel through the wafer mounting plate, providing a fluid pathway through the wafer mounting plate;
a vacuum manifold disposed over the wafer mounting plate and in fluid communication with the vacuum channel;
vacuum means for applying a vacuum through the vacuum manifold and vacuum channel;
a plurality of downwardly extending protrusions on the bottom surface of the wafer mounting plate;
whereby a wafer may be secured to the bottom of the wafer mounting plate through operation of the vacuum means and the wafer mounting plate may be deformed by application of fluid pressure or suction to the shape control plenum.

2. The wafer carrier of claim 1, wherein the protrusions are cylindrical protrusions.

3. The wafer carrier of claim 1, wherein the protrusions are cylindrical protrusions with a diameter of about 0.53975 mm ( 1/32″) and height of about 0.53975 mm ( 1/32″), spaced about 1.5875 mm ( 1/16″) apart.

4. The wafer carrier of claim 1, wherein the wafer mounting plate comprises a ceramic material.

5. The wafer carrier of claim 1, where in wafer mounting plate comprises a rigid material, with a thickness sufficient to ensure that upon application of suction through the wafer mounting plate, a wafer will conform to the shape of the bottom of the wafer mounting plate, but thin enough such that the wafer mounting plate may be deformed by the application of pressure or vacuum to the shape control plenum.

6. The wafer carrier of claim 1, where in wafer mounting plate comprises a rigid material, with a thickness sufficient to ensure that upon application of suction through the wafer mounting plate, a wafer will conform to the shape of the bottom of the wafer mounting plate, but thin enough such that the wafer mounting plate may be deformed by about 5 microns per PSI by the application of pressure or vacuum, in the range of 10 psi of pressure to 10 psi of vacuum, to the shape control plenum.

6. The wafer carrier of claim 1, wherein the wafer mounting plate preformed with a flat bottom surface.

7. The wafer carrier of claim 1, wherein the wafer mounting plate preformed with a convex bottom surface.

8. The wafer carrier of claim 1, wherein the wafer mounting plate preformed with a concave bottom surface.

9. A method of polishing a wafer in a CMP process, said method comprising the steps of:
providing a wafer carrier comprising:
a manifold plate, plenum ring and wafer mounting plate defining a shape control plenum;
a retaining ring coaxially disposed about the wafer mounting plate and defining, in conjunction with a lower surface of the wafer mounting plate, a space configured to accommodate a wafer;
fluid supply means for providing pressurized fluid or suction to the shape control plenum;
at least one vacuum channels through the wafer mounting plate, providing a fluid pathway through the wafer mounting plate;
a vacuum manifold disposed over the wafer mounting plate and in fluid communication with the vacuum channels;
vacuum means for applying a vacuum through the vacuum manifold and vacuum channels;
a plurality of downwardly extending protrusions on the bottom surface of the wafer mounting plate;
placing a wafer below the wafer mounting plate and applying vacuum to the wafer to secure the wafer to the mounting plate;
applying pressure or vacuum to the shape control plenum to alter the shape of the wafer mounting plate; and
rotating the wafer carrier over a polishing pad to polish a surface of the wafer.
